(19) United States
(12) Patent Application Publication
(10) Pub. No.: US 2015/0221481 A1
(43) Pub. Date: Aug. 6, 2015

(54) ELECTROSTATIC CHUCK WITH MAGNETIC CATHODE LINER FOR CRITICAL DIMENSION (CD) TUNING

(71) Applicants: Michael D. Willwerth, Campbell, CA (US); Chih-Hsun Hsu, Campbell, CA (US); Valentin N. Todorow, Palo Alto, CA (US)

(72) Inventors: Michael D. Willwerth, Campbell, CA (US); Chih-Hsun Hsu, Campbell, CA (US); Valentin N. Todorow, Palo Alto, CA (US)

(21) Appl. No.: 14/169,528

(22) Filed: Jan. 31, 2014

(51) Int. Cl. H01J 37/32; H01L 21/67; H01L 21/683

(52) U.S. Cl. CPC H01J 37/32715; H01L 21/6833; H01L 21/67115

(57) ABSTRACT

Electrostatic chucks with magnetic cathode liners for critical dimension (CD) tuning are described. For example, an electrostatic chuck (ESC) includes a cathode region. A wafer processing region is disposed above the cathode region. A magnetic cathode liner surrounds the cathode region, below the wafer processing region. The magnetic cathode liner is configured to provide magnetic field tuning capability for the ESC.

### BACKGROUND

1) Field

Embodiments of the present invention pertain to the field of semiconductor processing equipment and, in particular, to electrostatic chucks with magnetic cathode liners for critical dimension (CD) tuning.

2) Description of Related Art

In a plasma processing chamber, such as a plasma etch or plasma deposition chamber, the plasma density is often an important parameter to control during a process since it can correspond to the amount of ionization available at a location within the plasma.

Often, plasma characteristics can be manipulated by thermal means, where a change in the temperature of the plasma can lead to a change in plasma characteristics. For example, a temperature of a substrate holder, commonly called a chuck or pedestal, may be controlled to heat/cool a workpiece to various controlled temperatures during the process recipe (e.g., to control an etch rate). Similarly, a temperature of a showerhead/upper electrode, chamber liner, baffle, process kit, or other component may also be controlled during the process recipe to influence the processing. Conventionally, a heat sink and/or heat source is coupled to the processing chamber to maintain the temperature of a chamber component at a desired temperature. Often, at least one heat transfer fluid loop thermally coupled to the chamber component is utilized to provide heating and/or cooling power. Long line lengths in a heat transfer fluid loop, and the large heat transfer fluid volumes associated with such long line lengths are detrimental to temperature control response times. Point-of-use systems are one means to reduce fluid loop lengths/volumes. However, physical space constraints disadvantageously limit the power loads of such point-of-use systems.

With plasma processing trends continuing to increase RF power levels and also increase workpiece diameters (with 300 mm now typical and 450 mm systems now under development), temperature and/or RF control and distribution addressing both a fast response time and high power loads is advantageous in the plasma processing field. Temperature-based or temperature-only solutions may not achieve the optimal tunability of plasma density. As such, advances are still needed toward plasma density tunability.

### SUMMARY

Embodiments of the present invention include with magnetic cathode liners for critical dimension (CD) tuning, where a cathode liner may be included in an electrostatic chuck.

In an embodiment, an electrostatic chuck (ESC) includes a cathode region. A wafer processing region is disposed above the cathode region. A magnetic cathode liner surrounds the cathode region, below the wafer processing region. The magnetic cathode liner is configured to provide magnetic field tuning capability for the ESC.

In another embodiment, a semiconductor processing system includes a chamber coupled to an evacuation device, a gas inlet device, a plasma ignition device, and a detector. A computing device is coupled with the plasma ignition device. A voltage source is coupled with a sample holder that includes an electrostatic chuck (ESC). The ESC is disposed in the chamber and includes a cathode region. The ESC also includes a wafer processing region disposed above the cathode region. The ESC also includes a magnetic cathode liner surrounding the cathode region, below the wafer processing region. The magnetic cathode liner is configured to provide magnetic field tuning capability for the ESC. The magnetic cathode liner includes one or more electromagnets. The semiconductor processing system also includes an electrical source coupled to the one or more electromagnets of the magnetic cathode liner.

In another embodiment, an electrostatic chuck (ESC) includes a ceramic plate having a front surface and a back surface, the front surface for supporting a wafer or substrate. A base is coupled to the back surface of the ceramic plate. A plurality of pixelated elements is disposed in the base. A magnetic cathode liner surrounds the ceramic plate and base. The magnetic cathode liner and the plurality of pixelated elements are configured to provide plasma tuning capability in regions local to the ESC.

### BRIEF DESCRIPTION OF THE DRAWINGS

FIG. 1 illustrates a cross-sectional view of an electrostatic chuck having a conventional cathode liner.

FIG. 2 illustrates a cross-sectional view of an electrostatic chuck having a magnetic cathode liner, in accordance with an embodiment of the present invention.

FIG. 3 illustrates a cross-sectional view of a magnetic cathode liner for an electrostatic chuck, in accordance with an embodiment of the present invention.

FIG. 4 illustrates an angled partial cross-sectional view of an electrostatic chuck having a magnetic cathode liner coupled to a wire passage tube, in accordance with an embodiment of the present invention.

FIG. 5 illustrates a cross-sectional view of a portion of an electrostatic chuck having a magnetic cathode liner, in accordance with an embodiment of the present invention.

FIG. 6A is a plot of Cl₂⁺ Flux as a function of radius for a standard mode plasma, in accordance with an embodiment of the present invention.

FIG. 6B is a plot of Cl₂⁺ Flux as a function of radius for a reverse mode plasma, in accordance with an embodiment of the present invention.

FIG. 7A is a plot of Ion Flux as a function of radius for an argon (Ar) plasma, in accordance with an embodiment of the present invention.

FIG. 7B is a plot of Ion Flux as a function of radius for a chlorine (Cl₂) plasma, in accordance with an embodiment of the present invention.

FIG. 8 illustrates a cross-sectional view of a portion of an electrostatic chuck (ESC) configured to support a wafer or substrate, in accordance with another embodiment of the present invention.

FIG. 9 illustrates a cross-sectional view of a portion of an electrostatic chuck (ESC) configured to support a wafer or substrate, in accordance with another embodiment of the present invention.

FIG. 10 illustrates a side schematic view of a substrate support, in accordance with some embodiments of the present invention.

FIG. 11 illustrates a system in which an electrostatic chuck having a magnetic cathode liner can be housed, in accordance with an embodiment of the present invention.

FIG. 12 illustrates a block diagram of an exemplary computer system, in accordance with an embodiment of the present invention.

### DETAILED DESCRIPTION

Electrostatic chucks with magnetic cathode liners for critical dimension (CD) tuning are described. In the following description, numerous specific details are set forth, such as specific chuck and/or chamber configurations, in order to provide a thorough understanding of embodiments of the present invention. It will be apparent to one skilled in the art that embodiments of the present invention may be practiced without these specific details. In other instances, well-known aspects, such as etch processing in the presence of a wafer supported by a chuck, are not described in detail in order to not unnecessarily obscure embodiments of the present invention. Furthermore, it is to be understood that the various embodiments shown in the Figures are illustrative representations and are not necessarily drawn to scale.

One or more embodiments described herein are directed to a magnetic cathode liner for critical dimension (CD) tuning during plasma processing. For example, to offer additional tuning capabilites near the edge of the wafer during plasma processing, an electromagnetic coil is added under the wafer near the wafer edge. The electromagnetic coil is direct current (DC)-powered and can be adjusted in voltage to allow for edge tuning of the etch critical dimensions. In certain embodiments, electromagnets are used, as opposed to permanent magnets, for responsive control. In an exemplary implementation, a chamber having a dual plasma source (DPS) is equipped with a cathode having a liner with an electromagnetic coil provided therein. Electrical wires for the electromagnets may be routed through passageways at atmosphere to the outside of the chamber. In one embodiment, by altering a plasma density and distribution, the plasma impinging the electrostatic chuck (ESC) or chamber wall can be controlled. In one embodiment, with the magnetic field, the charged particle trajectory may be deflected away from the wafer. As such, “fall on” particles that otherwise arrive onto the wafer and cause yield loss may be avoided.

To provide context, demand for very uniform wafer temperature and plasma density tunability on an electrostatic chuck is ever increasing. In general, wafer clamping by means of electrostatic chucking has been used to provide temperature control during etch processing. The wafer is clamped to a ceramic or multi-layer surface with a heat sink or heater (or both) depending on application. Due to inherent non-uniformities and auxiliary hardware (e.g., lifter pins, RF/DC electrode(s), etc.) the ceramic surface temperature is not uniform. This non-uniformity translates to the wafer, affecting the etch process. Conventional chuck designs have concentrated on coolant layout optimization and introduction of multiple (up to 4 zones) heaters. Such chuck designs have not been useful for solving issue related to, or caused by, auxiliary hardware (e.g., lifter pins, RF/DC electrode(s), etc.).

More specifically, conventional electrostatic chuck temperature control is typically based on a cooling base and one or more electrical heaters included in the electrostatic chuck. Such an arrangement, however, can have flaws or drawbacks that lead to some level of temperature non-uniformity. For example, bond imperfection between the ceramic layer of the electrostatic chuck and an underlying cooling base which results in thickness variation between the ceramic plate and cooling base can lead to the formation of cold or hot spots across the check. In an example of particular significance to the present disclosure, plasma density variation, e.g., in a plasma etch or deposition chamber, can lead to the formation of hot or cold spots across a wafer or substrate supported by the chuck or pedestal. In accordance with an embodiment of the present invention, as described herein, a magnetic cathode liner is included to surround an electrostatic chuck in order to provide capability to provide a finely tuned magnetic field for the plasma near the chuck. The finely tuned magnetic field can be used to tune plasma density and, hence, plasma uniformity at or near a sample. Embodiments described herein may be directed to next generation etch chamber ESCs with active magnetic field control.

It is appreciated that magnetron reactive ion etching (RIE) has been employed to provide global magnetic field control over an associated plasma density. However, control in on a localized level is not achievable with such processes or associated apparatuses. By contrast, as described in association with embodiments herein, an ESC having a magnetic cathode liner provides fine tuned magnetic field tuning capability for controlling plasma ionization more local to the chuck.

In accordance with one or more embodiments described herein, an electromagnetic tuning feature is provided to tune critical dimension uniformity (CDU) at the wafer level. In one such embodiment, one or more electromagnets are included in a cathode liner. The resulting magnetic cathode liner may be provided as part of an electrostatic chuck used to hold a wafer during plasma processing, such as plasma etching.

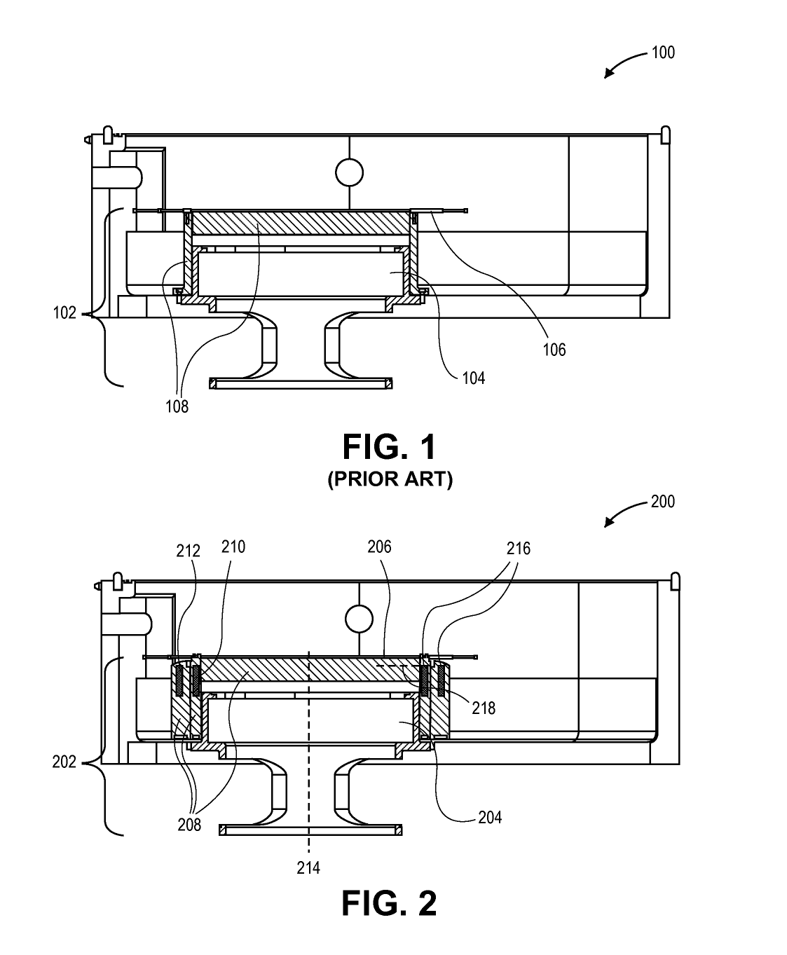

For comparative purposes, FIG. 1 illustrates a cross-sectional view of an electrostatic chuck having a conventional cathode liner. Referring to FIG. 1, a portion 100 of a plasma processing chamber includes an electrostatic chuck (ESC) 102. The ESC 102 includes a cathode region 104 and a wafer processing region 106 above the cathode region 104. A cathode liner 108 surrounds the cathode region 104 below the wafer processing region 106.

FIG. 2 illustrates a cross-sectional view of an electrostatic chuck having a magnetic cathode liner, in accordance with an embodiment of the present invention. Referring to FIG. 2, a portion 200 of a plasma processing chamber includes an electrostatic chuck (ESC) 202. The ESC 202 includes a cathode region 204 and a wafer processing region 206 above the cathode region 204. A cathode liner 208 surrounds the cathode region 204 below the wafer processing region 206. In an embodiment, the cathode liner 208 is a magnetic cathode liner that includes one or more electromagnets. For example, in an embodiment, the magnetic cathode liner 208 includes two electromagnets 210 and 212, as depicted in FIG. 2. In one such embodiment, the magnetic cathode liner 208 includes a first ring-shaped electromagnet 210 having a first diameter, and a second ring-shaped electromagnet 212 having a second, larger, diameter. In a specific such embodiment, the first and second ring-shaped electromagnets 210 and 212, respectively, share a common center point, e.g., they are centered around axis 214 of the ESC 202 of FIG. 2. In another embodiment, although not depicted, a plurality of individual electromagnets may be arranged in a ring-like fashion to provide, collectively, a ring-like electromagnet.

As is also depicted in FIG. 2, in one embodiment, the first and second ring-shaped electromagnets 210 and 212, respectively, have upper surfaces 216 that share a common plane 218 with respect to a cross-sectional orientation of the wafer processing region 206. In a particular such embodiment, the common plane 218 is below the wafer processing region 206 with respect to the cross-sectional orientation of the ESC 202.

In an embodiment, the electromagnets are powered by a direct current (DC) voltage and do not require an RF filter. In one embodiment, the electromagnets are composed of a magnetic material such as, but not limited to, metal wires, metal coils, ferrites and ferromagnetic materials. In an embodiment, the material of the cathode liner 208 housing the electromagnets is composed of a material such as, but not limited to, Alumina based ceramics, quartz and Yttrium based materials. It is to be appreciated that, in addition to the embodiments described above, the magnetic cathode liner 208 can house one or more than two electromagnets.

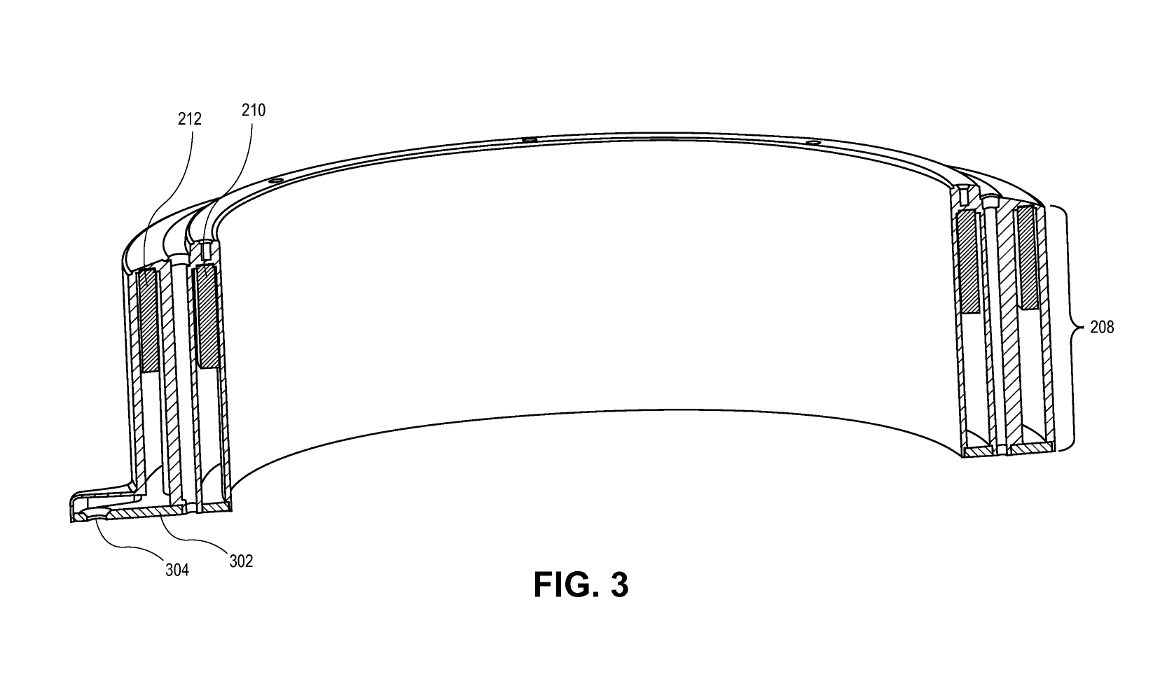

FIG. 3 illustrates a cross-sectional view of a magnetic cathode liner for an electrostatic chuck, in accordance with an embodiment of the present invention. Referring to FIG. 3, a blown up view of a portion of the magnetic cathode liner 208 of FIG. 2 is provided. In addition to the first and second ring-shaped electromagnets 210 and 212, a cover layer, such as an e-beam welded cover layer 302 is shown. Also depicted is a wire exit 304, which provides access of wiring from outside the process chamber (e.g., in an atmospheric portion) to the first and second ring-shaped electromagnets 210 and 212.

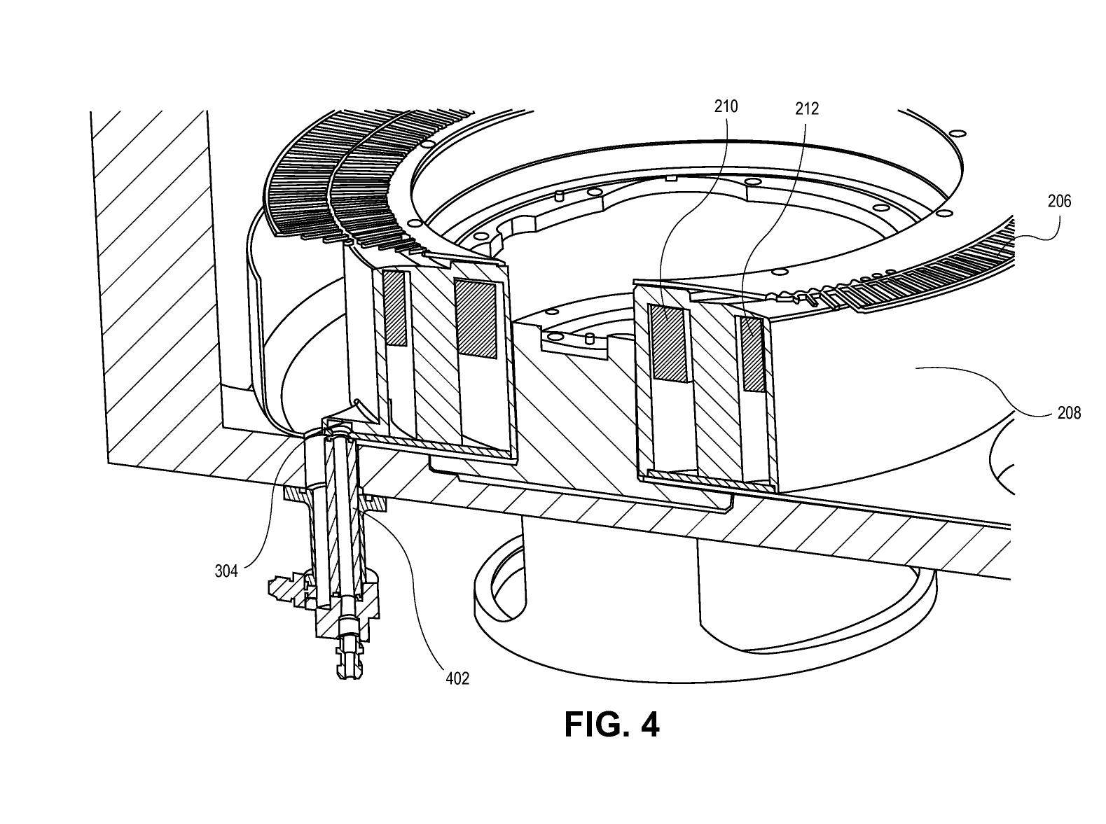

FIG. 4 illustrates an angled partial cross-sectional view of an electrostatic chuck having a magnetic cathode liner coupled to a wire passage tube. Referring to FIG. 4, the magnetic cathode liner 208, the first and second ring-shaped electromagnets 210 and 212, and the wafer processing region 206 described in association with FIG. 2 are shown. Additionally, the wire exit 304 described in association with FIG. 3 is shown. Also depicted is a wire passage tube 402 which is coupled to the wire exit 304. In one embodiment, the wire passage tube 402 is a separate tube having O-rings at both ends to allow for wire passage through to atmospheric conditions outside of the process chamber.

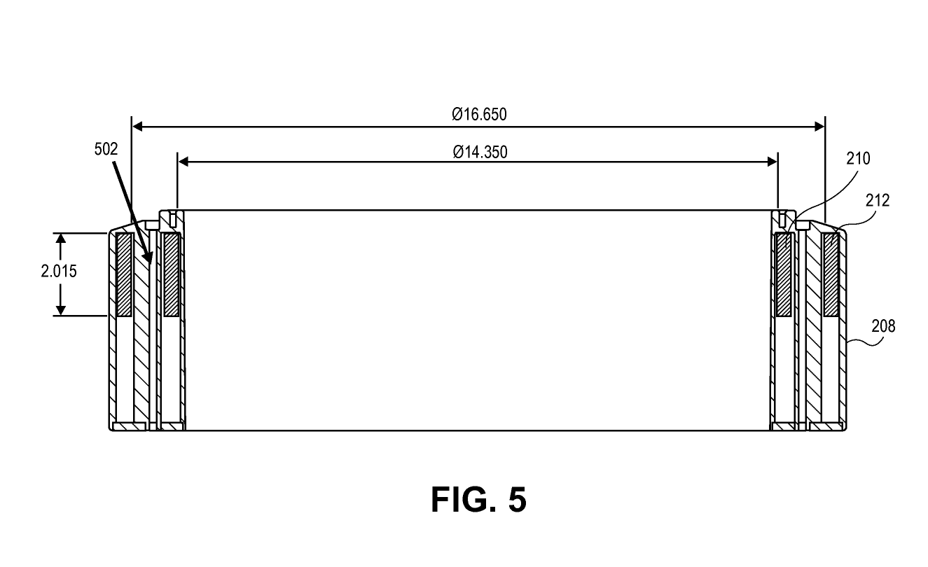

FIG. 5 illustrates a cross-sectional view of a portion of an electrostatic chuck having a magnetic cathode liner. Referring to FIG. 5, exemplary sizing for a magnetic cathode liner 208 is shown. For example, in one embodiment, the first ring-shaped electromagnet 210 has an inner diameter of approximately 14 inches, while the second ring-shaped electromagnet 212 has an inner diameter of approximately 17 inches. The height of the first and second ring-shaped electromagnets 210 and 212 is approximately 2 inches. In an embodiment, for such sizing, at location 502, a magnetic field of approximately 450 Gauss can be achieved.

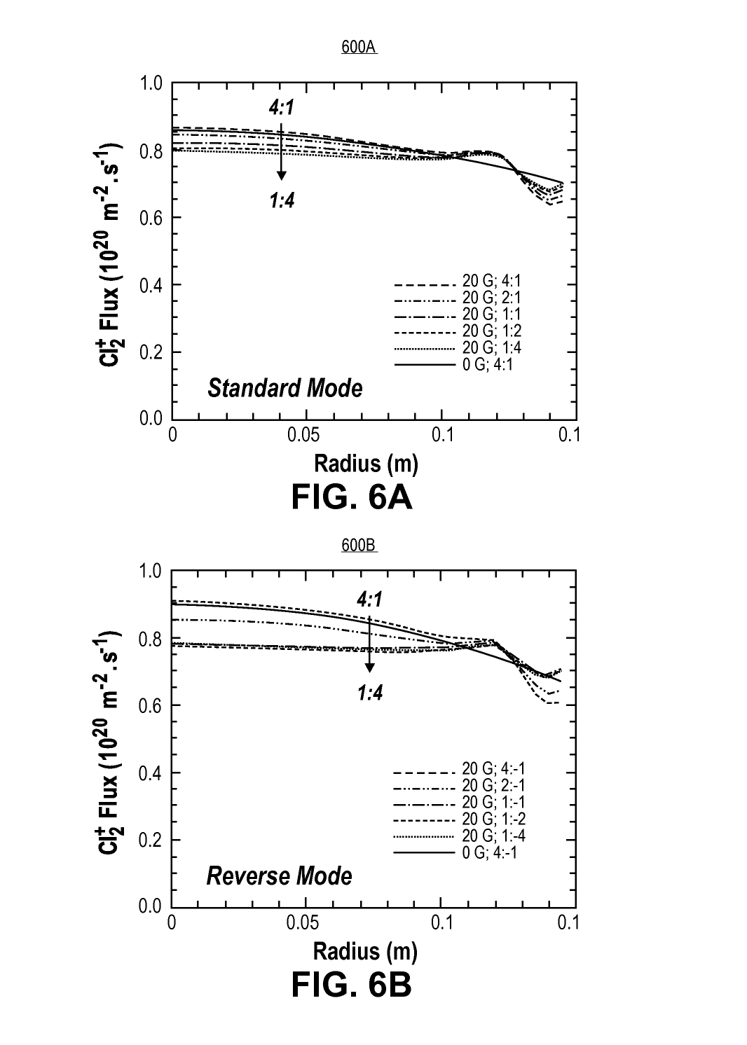

In an embodiment, use of a magnetic cathode liner such as the magnetic cathode liners described above can be beneficial since it has been determined that ion flux is influenced by the presence of a magnetic field. For example, FIG. 6A is a plot 600A of Cl₂⁺ Flux as a function of radius for a standard mode plasma, in accordance with an embodiment of the present invention. FIG. 6B is a plot 600B of Cl₂⁺ Flux as a function of radius for a reverse mode plasma, in accordance with an embodiment of the present invention. Both cases tested involved a Cl₂-based plasma at 10 mTorr for an unbiased 500 Watt inductively coupled plasma (ICP). In the standard mode, even though ion flux near the wafer center decreases, the radial flux profile is less sensitive to current ratio between the coils due to low pressure. As a result, peak location shifts radially outward with increasing outer coil current. In the reverse mode, a strong effect is observed when shifting from inner-dominant to outer-dominant current. The sensitivity however is very weak when outer current dominates. As a result, peak location shifts radially outward with increasing outer coil current. In either case, the magnetic field is approximately 4 Gauss at the wafer level.

In another aspect, one or more embodiments described herein relate to electrostatic chucks with magnetic cathode liners for CD tuning and having additional variable magnetic control within the surface area of the processing region of the chuck. In particular, variable pixelated magnetic field generation may be incorporated into a bonded electrostatic chuck using individualized electrical wiring and a control system to power the individualized wiring for each element in a pixelated arrangement. Applications may include increased plasma density uniformity control for pedestals or electrostatic chucks, e.g., as included in semiconductor processing chambers. Particular embodiments involve the incorporation of a plurality of electromagnets as embedded in an electrostatic chuck for independent and local process control at the wafer level.

To further demonstrate the concepts at hand, when applying a magnetic field at the wafer level, electrons gyrate around the magnetic field lines and are trapped as a local ionization source. The trapping leads to higher plasma density locally. In addition, the recombination with an associated chamber wall with a magnetic field may be reduced. The gyrofrequency of an electron is provided by equation 1 (eq. 1):

(ω=qB/mₑ. (eq. 1)

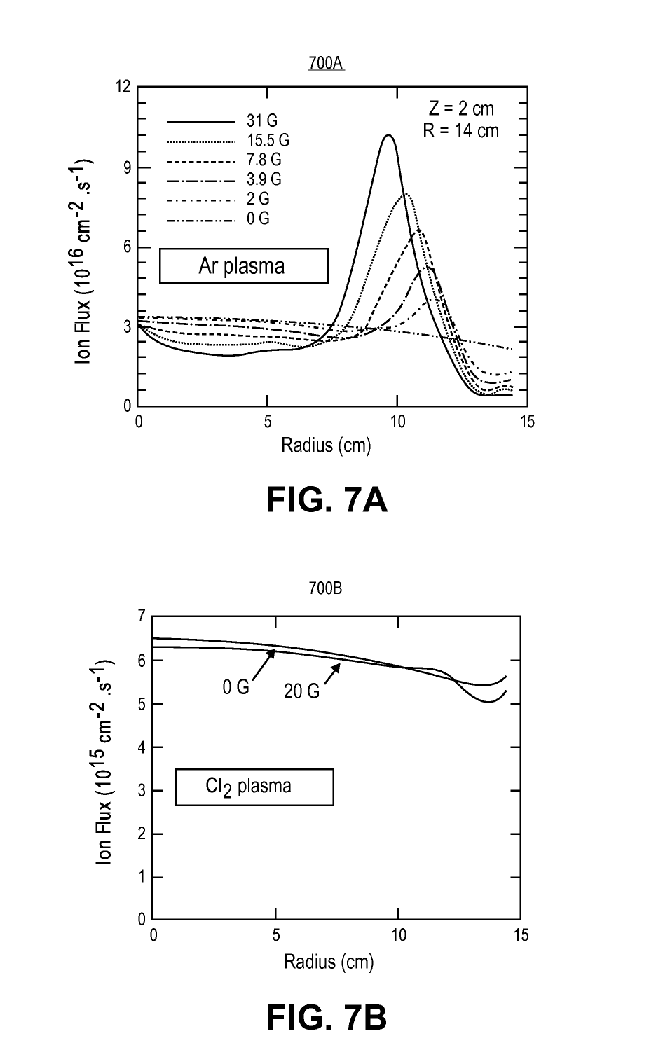

Simulation results indicate that a magnetic field of approximately 4 Gauss is strong enough to deviate the ion flux by ±5%, even in the presence of bias in a Cl₂ plasma. For example, FIG. 7A is a plot 700A of Ion Flux as a function of radius for an argon (Ar) plasma, in accordance with an embodiment of the present invention. Referring to plot 700A, an Ar plasma is formed at a density of 10 mTorr and a power of 500 W, with no bias. FIG. 7B is a plot 700B of Ion Flux as a function of radius for a chlorine (Cl₂) plasma, in accordance with an embodiment of the present invention. Referring to plot 700B, a Cl₂ plasma is formed at a density of 10 mTorr and a power of 300 W, with a 350 W bias. Referring to both plots 700A and 700B, peak magnetic fields are indicated at 14 cm radial location and 2 cm below the wafer. Ion flux deviation from baseline (i.e., with no magnetic field) decreases in the presence of bias.

In principle, as described above, with a magnetic field at the wafer level, the plasma undergoes gyration motion. The magnetic field can be controlled or tuned using the above described magnetic cathode liner. Additionally, in an embodiment, plasma density is further tuned (e.g., increased) locally by using localized electromagnets included in an electrostatic chuck. Together, the magnetic field introduced around the wafer can cause the local electron accelerated in cyclic motion, leading to locally enhanced molecular dissociation.

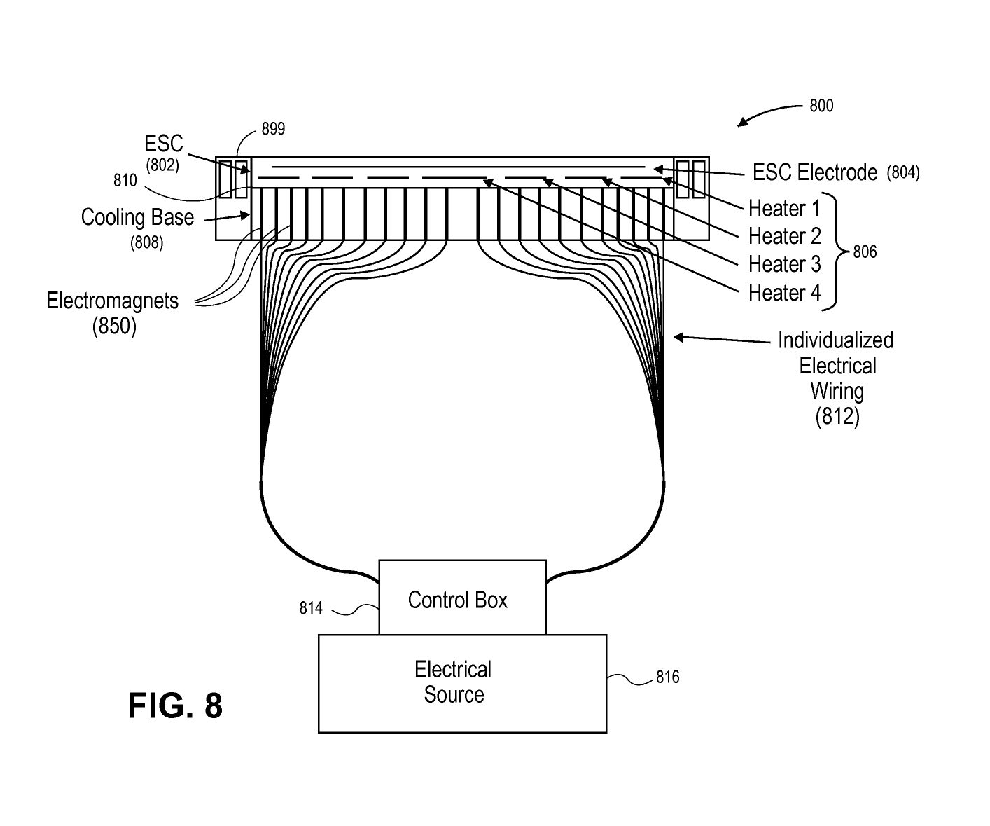

As a general example, FIG. 8 illustrates a cross-sectional view of a portion of an electrostatic chuck (ESC) configured to support a wafer or substrate, in accordance with an embodiment of the present invention. Referring to FIG. 8, a pixelated electrostatic chuck 800 includes an electrostatic chuck top portion 802 (e.g., an Al₂O₃ or like solid ceramic plate). The electrostatic chuck portion includes an ESC electrode 804 (e.g., for RF applications) and a plurality of main heaters 806, such as heaters 1, 2, 3 and 4, etc. In the embodiment shown, a single or mono-polar ESC electrode configuration is used. The ESC portion 802 is bonded to a cooling base 808 through a bonding layer 810. A plurality of electromagnets 850 is disposed in the cooling based 808. Each of the plurality of electromagnets 850 is coupled to a control box 814 by an associated individualized electrical wiring 812. The control box 814 may be further coupled to an electrical source 816, and can independently control power to each of the electromagnets 850 via the associated individualized electrical wiring 812. As such, the configuration of pixelated electrostatic chuck 800 includes pixelated electromagnet routing on the back side of the electrostatic chuck. Additionally, the electrostatic chuck 800 includes a magnetic cathode liner 899 surrounding the ESC portion 802. The magnetic cathode liner 899 may be as described above in association with FIGS. 2-5.

In an embodiment, the plurality of electromagnets 850 is disposed in the cooling based 808 at a level approximately 1 centimeter or less below the electrostatic chuck top portion 802. In one such embodiment, the plurality of electromagnets 850 is disposed in the cooling based 808 at a level approximately in the range of 5-8 mm below the electrostatic chuck top portion 802. In an embodiment, the cooling base 808 includes a chiller plate with an aluminum (Al) body and capability for fluid flow there through.

In another aspect, one or more embodiments described herein relate to electrostatic chucks with magnetic cathode liners for CD tuning and having additional variable temperature control within the surface area of the processing region of the chuck. In particular, variable pixelated heat generation may be incorporated into a bonded electrostatic chuck using individualized electrical wiring and a control system to power the individualized wiring for each element in a pixelated arrangement. Applications may include increased plasma density uniformity control for pedestals or electrostatic chucks, e.g., as included in semiconductor processing chambers. Particular embodiments involve the incorporation of a plurality of light pipes as embedded in an electrostatic chuck for independent and local process control at the wafer level. As such, light energy may be used instead of or in addition to thermal resistance for fine tuning of temperature uniformity. One or more advantages of implemental discrete temperature control by light heating include, but are not limited to, (1) the ability to heat specific area(s) of a pedestal or electrostatic chuck, (2) special perforated bonding can allow direct heating of a back side of a ceramic chuck or pedestal, (3) RF interface issue mitigation as heating is light based, (4) a control system which allows only specific fibers are used for heating based on cold spot mapping.

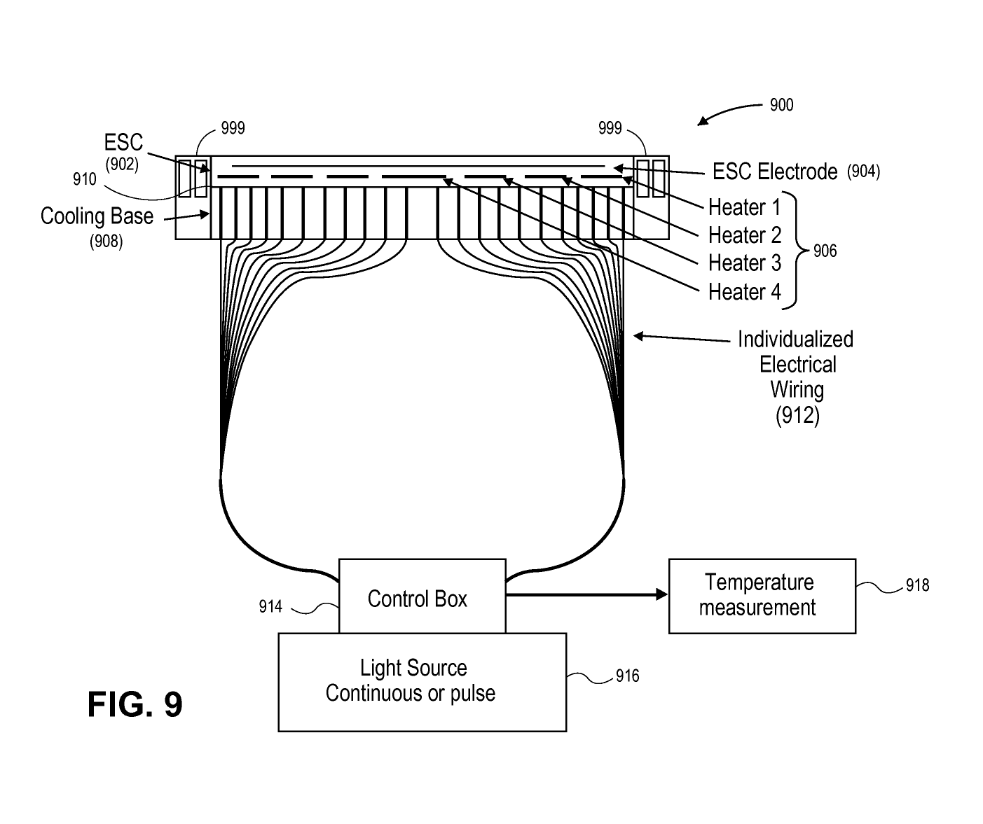

In an exemplary embodiment, FIG. 9 illustrates a cross-sectional view of a portion of an electrostatic chuck (ESC) configured to support a wafer or substrate, in accordance with an embodiment of the present invention. Referring to FIG. 9, a pixelated electrostatic chuck 900 includes an electrostatic chuck portion 902 (e.g., an Al₂O₃ or like solid ceramic plate). The electrostatic chuck portion includes an ESC electrode 904 (e.g., for RF applications) and a plurality of main heaters 906, such as heaters 1, 2, 3, 4, etc. In the embodiment shown, a single or mono-polar ESC electrode configuration is used. The ESC portion 902 is bonded to a cooling base 908 through a bonding layer 910. A plurality of fibers/light carrying medium 912 is disposed in the cooling base 908. The plurality of fibers/light carrying medium 912 is coupled to a control box 914. The control box 914 may be further coupled to a light source 916, such as a continuous or pulse light source. As such, the configuration of pixelated electrostatic chuck 900 includes fiber optic routing on the back side of the electrostatic chuck. As described in greater detail below, the control box may include or be coupled to a temperature measurement device 918, as is depicted in FIG. 9. Additionally, the electrostatic chuck 900 includes a magnetic cathode liner 999 surrounding the ESC portion 902. The magnetic cathode liner 999 may be as described above in association with FIGS. 2-5.

Referring again to FIG. 9, apparatus 900 has three level of temperature control: the first level provided by the cooling base 908 (e.g., as a chiller plate with an Al body and capability for fluid there through), the second level provided by the electrical heaters 906, and the third level provided by the fibers/light carrying medium 912 which provide light for heating, e.g., with pixelated individual die control by light heating. By providing all three levels of temperature control, in an embodiment, less than 1 degree non-uniformity over a 300 mm plate may be achieved. For example, in accordance with an embodiment of the present invention, an electrostatic chuck (ESC) has 1 or more (e.g., up to 8) main heaters to along with a cooling base to provide baseline temperature control. To provide fine-tuning of temperature distribution, a large number of light heating elements (e.g., light pipes, fiber optics, etc.) is position at the back of the ESC. To reduce RF-related non-uniformity, the fine-tuning light heaters are not resistance based. Thus, in an embodiment, etch processing with improved RF uniformity and/or improved temperature uniformity can be achieved. Additional fine tuning of plasma conditions is provided by the magnetic cathode liner 999, as is described above.

In another embodiment, in place of a plurality of fibers/light carrying medium 912, a plurality of resistive heaters may be provided to enable pixilated temperature control of the electrostatic chuck.

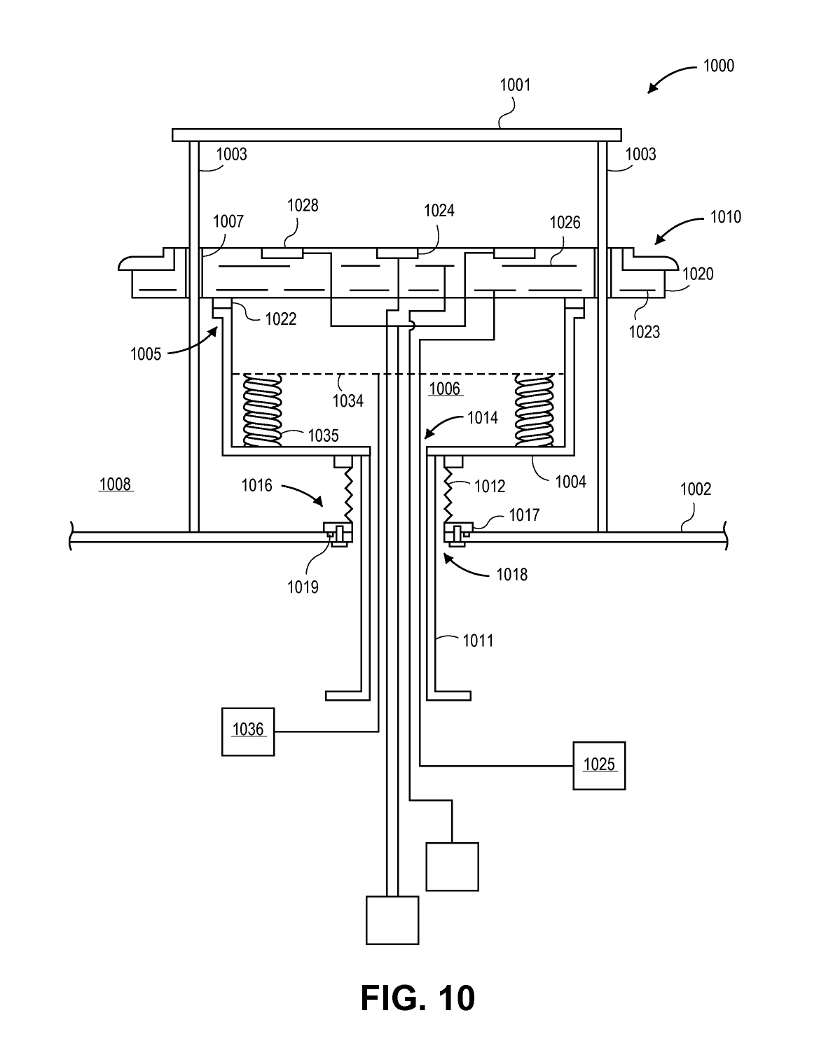

As described above, magnetic field tunability may be provided for an electrostatic chuck by including a magnetic cathode liner for the electrostatic chuck. As an example, FIG. 10 illustrates a side schematic view of a substrate support suitable for use in conjunction with a magnetic cathode liner, in accordance with some embodiments of the present invention. More particularly, FIG. 10 depicts a side schematic view of a substrate support 1000. As illustrated in FIG. 10, the substrate support 1000 is configured in a loading position to either receive or remove a substrate 1001. For example, as illustrated in FIG. 10 and in the loading position, the substrate 1001 may rest on a plurality of lift pins 1003 above the substrate support 1000. The lift pins 1003 are movable with respect to a support surface of the substrate support 1000, for example, via lift pin holes 1007 that facilitate relative movement of the lift pins 1003. The substrate support 1000 may be disposed in a process chamber (a cut away view of a chamber wall 1002 is illustrated in FIG. 10). The process chamber may be any suitable substrate processing chamber.

The substrate support 1000 may include a body 1004. The body 1004 may have an interior volume 1006 that is separated from a processing volume 1008 of the process chamber. The interior volume 1006 may be held at atmosphere, for example, about 14.7 pounds per square inch (psi), or be held under an inert atmosphere, such as nitrogen (N₂) or the like. The interior volume 1006 is further isolated from, and protected from, any gases that may be present in the processing volume 1008 of the process chamber. The process volume 1008 may be held at atmospheric or sub-atmospheric pressures.

The interior volume 1006 may be enclosed by an electrostatic chuck 1010 at an upper end 1005 of the body 1004 and by a feed through structure 1011, which may be welded or brazed to a lower opening 1014 of the body 1004. For example, as illustrated in FIG. 10, a bellows 1012 may surround at least a portion of the feed through structure 1011 and isolate the processing volume 1008 from the exterior of the chamber and the interior volume 1006. The bellows 1012 may provide both a flexible section to facilitate motion of the substrate support 1000 and a pathway for providing gases, electrical power, coolants at the like to the substrate support 1000. The gases, electrical power, coolant and the like may be by provided via the feed through structure 1011.

The bellows 1012 may be coupled to the body 1004 at the lower opening 1014, for example, by welding or brazing. An opposing lower end 1016 of the bellows 1012 may be coupled to an opening 1018 in the chamber wall 1002. For example, as illustrated in FIG. 10, the lower end 1016 of the bellows 1012 may include a flange 1017 which may be coupled via an o-ring 1019, or copper gasket or the like to the chamber wall 1002. The o-ring 1019 may rest in a groove on the processing volume facing surface of the chamber wall 1002. Other designs and coupling of the bellows 1012 to the body 1004 and the chamber wall 1002 are possible.

The substrate support 1000 may include a cooling plate 1034 disposed in the interior volume 1006 below the electrostatic chuck 1010. For example, in some embodiments, the cooling plate 1034 may be directly contacting an interior volume facing surface of the electrostatic chuck 1010. However, this embodiment of the cooling plate 1034 is merely exemplary and the cooling plate may not directly contact the electrostatic chuck 1010. The cooling plate 1034 may include a plurality of cooling channels (not shown) for circulating a coolant there through. The coolant may include any suitable liquid or gas coolant. In some embodiments, the coolant may be supplied to the cooling plate 1034 via a coolant source 1036 coupled to the cooling plate 1034 via the feed through structure 1011. For example, the cooling plate 1034 may be engaged to the electrostatic chuck 1010 by one or more springs 1035 or any suitable engagement mechanism.

In some embodiments, the cooling plate 1034 may include an inner and outer cooling plate. In some embodiments, the inner cooling plate may be disposed about a center gas line, and the outer cooling plate may be disposed about a plurality of outer gas lines. For example, the inner and outer cooling plates may be used to adjust cooling capacity depending on how the electrostatic chuck 1010 is utilized, such as how electrical power is provided to the electrode(s) 1026 and/or the one or more heaters 1023 or the like. Further, the inner and outer cooling plates may be utilized to improve substrate temperature control or cool down the substrate support 1000 from high temperatures. For example, the inner and outer cooling plates may be modulated to control heat transfer between the one or more heaters 1023 and the substrate 1001.

In some embodiments, the cooling plate 1034 may include an upper and a lower cooling plate. The upper and lower cooling plates may be utilized to provide similar benefits as discussed above for the inner and outer cooling plates. The upper and lower cooling plates may be stacked such that upper cooling plate contacts the electrostatic chuck 1010 via a foil while lower cooling plate contacts upper cooling plate. By independently controlling the flow of coolant to the upper and lower cooling plates, variable heat transfer is achieved between ceramic body 1020 and cooling plate assembly 1034. In some embodiments, each of the upper and lower cooling plates may provide uniform cooling over the entire diameter of cooling plate 1034. In other embodiments, each of upper and lower cooling plates may provide different cooling to inner and outer regions of cooling plate 1034. That is, in some embodiments, upper and lower cooling plates may be combined with inner and outer cooling plates.

The electrostatic chuck 1010, thus, may include a ceramic plate 1020. As illustrated in FIG. 10, the ceramic plate 1020 may rest on a ring 1022 disposed between the electrostatic chuck 1010 and the upper end 1005 of the body 1004. For example, the ring 1022 may comprise KOVAR™, or any suitable material. The ring 1022 may secure the electrostatic chuck 1010 to the upper end 1005 of the body 1004, for example, by welding or brazing the ring 1022 to both the electrostatic chuck 1010 and the upper end 1005 of the body 1004. The ceramic plate 1020 may comprise any suitable ceramic material, such as aluminum nitride (AlN), aluminum oxide (Al₂O₃), or a doped ceramic, such as titania doped alumina or calcium doped aluminum nitride or the like. As illustrated in FIG. 10, the ceramic plate 1020 may include a plurality of grooves 1024 formed in a substrate supporting surface of the ceramic plate 1020. The grooves may be used, for example, to provide a backside gas to a backside surface of the substrate 1001. The ceramic plate 1020 may further include an electrode or a plurality of electrodes 1026, where the electrode(s) 1026 may be used to secure the substrate 1001 a processing surface 1028 of the electrostatic chuck 1010.

FIG. 10 illustrates the electrode(s) 1026 in accordance with some embodiments of the invention. For example, as discussed above, the electrode(s) 1026 may be utilized to secure the substrate 1001 to the processing surface 1028 of the electrostatic chuck 1010. For example, in some embodiments, the electrode(s) 1026 may utilized for controlled de-chucking from the electrostatic chuck 610, to chuck bowed substrates, or the like. For example, during de-chucking, gas may still be flowing through the grooves 1024 and/or the pressure in the grooves may be higher than the pressure in the processing volume 1008. Accordingly, for example, to prevent the substrate 1001 from jumping off the electrostatic chuck 1010, in the case of a plurality of electrodes, some of the electrodes 1026 may be turned off prior to others to gradually de-chuck the substrate 1001. For example, during chucking, larger substrates, such as 300 millimeter or greater, may be bowed. Accordingly, to flatten a bowed substrate against the electrostatic chuck 1010, some of the electrodes 1026 may be operated at a higher power and/or frequency that others of the electrodes 1026 to flatten out the substrate.

As described above, the electrostatic chuck 1010 may further include one or more heaters 1023. The one or more heaters 1023 may be coupled to one or more power supplies 1025 and may be independently controllable. In some embodiments, the one or more heaters 1023 may include a plurality of heaters 1023, as illustrated in FIG. 10. For example, in some embodiments, the plurality of heaters 1023 may include a central heater, a middle heater disposed about the central heater, and an outer heater disposed about the middle heater. Each of the central, middle and outer heaters may be coupled to the same or separate one or more power supplies 1025 and independently controlled via a temperature feedback loop. For example, a first thermocouple may monitor a temperature of the ceramic plate 1020 proximate the location of the central heater. Similarly, additional thermocouples may perform a similar function for the middle and outer heaters. In accordance with one or more embodiments of the present invention, although not depicted, a magnetic cathode liner (such as described in association with FIGS. 2-5) is positioned around the perimeter of the cooling plate assembly 1034 and/or around the ceramic body 1020.

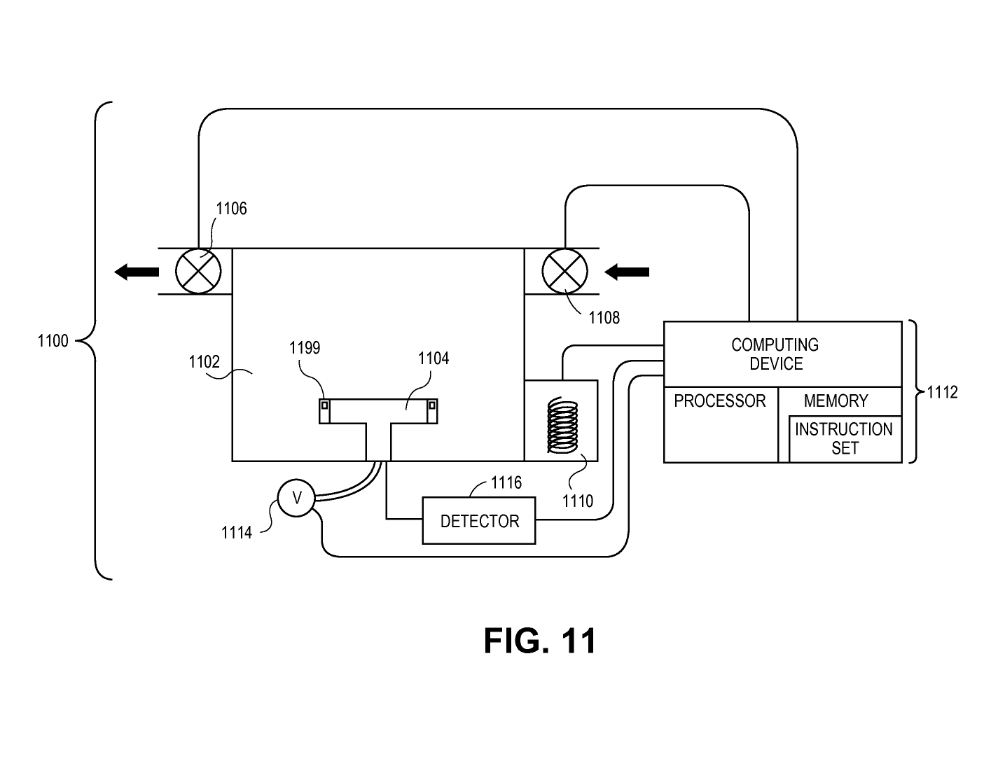

An electrostatic chuck having a magnetic cathode liner may be included in processing equipment suitable to provide an etch plasma in proximity to a sample for etching. For example, FIG. 11 illustrates a system in which an electrostatic chuck with a magnetic cathode liner can be housed, in accordance with an embodiment of the present invention.

Referring to FIG. 11, a system 1100 for conducting a plasma etch process includes a chamber 1102 equipped with a sample holder 1104 (e.g., an ESC having a magnetic cathode liner 1199 such as described above in association with FIGS. 2-5). An evacuation device 1106, a gas inlet device 1108 and a plasma ignition device 1110 are coupled with chamber 1102. A computing device 1112 is coupled with plasma ignition device 1110. System 1100 may additionally include a voltage source 1114 coupled with sample holder 1104 and a detector 1116 coupled with chamber 1102. Computing device 1112 may also be coupled with evacuation device 1106, gas inlet device 1108, voltage source 1114 and detector 1116, as depicted in FIG. 11.

Chamber 1102 and sample holder 1104 may include a reaction chamber and sample positioning device suitable to contain an ionized gas, i.e. a plasma, and bring a sample in proximity to the ionized gas or charged species ejected there from. Evacuation device 1106 may be a device suitable to evacuate and de-pressurize chamber 1102. Gas inlet device 1108 may be a device suitable to inject a reaction gas into chamber 1102. Plasma ignition device 1110 may be a device suitable for igniting a plasma derived from the reaction gas injected into chamber 1102 by gas inlet device 1108. Detection device 1116 may be a device suitable to detect an end-point of a processing operation. In one embodiment, system 1100 includes a chamber 1102, a sample holder 1104, an evacuation device 1106, a gas inlet device 1108, a plasma ignition device 1110 and a detector 1116 similar to, or the same as, a Conductor etch chamber or related chambers used on an Applied Materials® AdvantEdge system.

It is to be appreciated that although an etch chamber is described above, electrostatic chucks such as those described herein may instead be included in other semiconductor processing chambers. Examples of other suitable semiconductor processing chambers include, but are not limited to, chemical vapor deposition (CVD) or physical vapor deposition (PVD) process chambers.

Embodiments of the present invention may be provided as a computer program product, or software, that may include a machine-readable medium having stored thereon instructions, which may be used to program a computer system (or other electronic devices) to perform a process according to the present invention. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

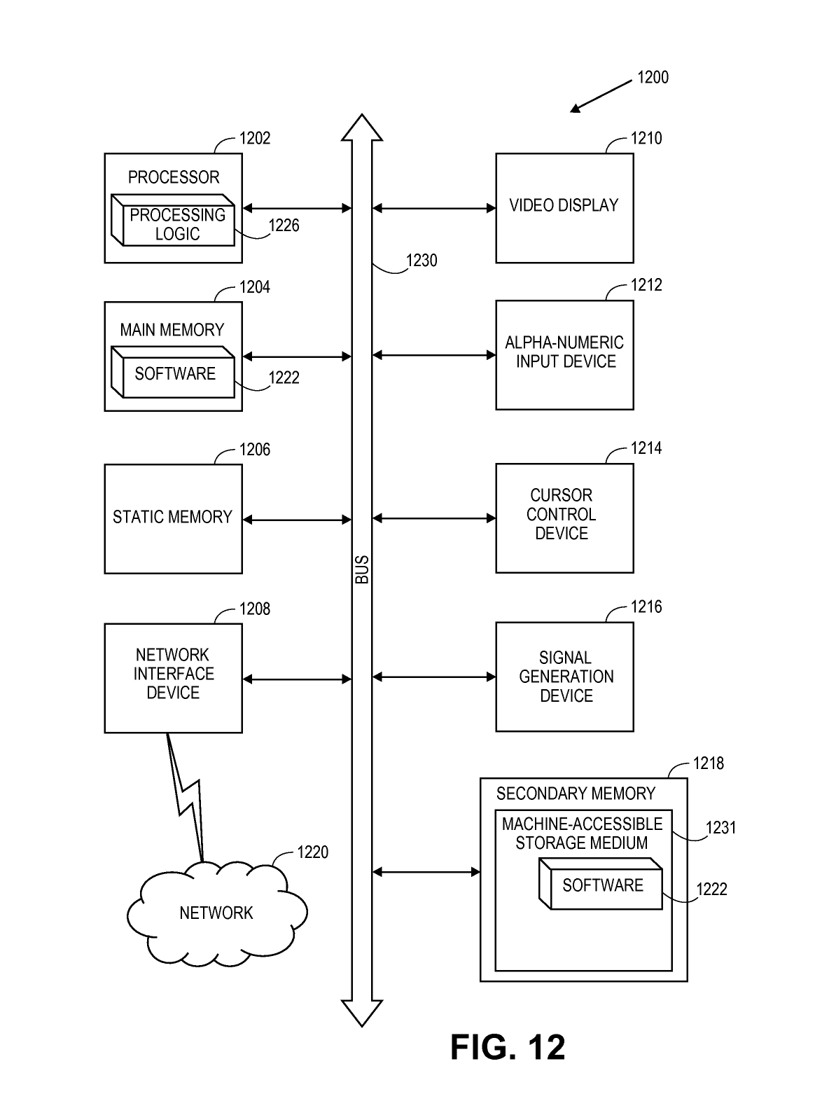

FIG. 12 illustrates a diagrammatic representation of a machine in the exemplary form of a computer system 1200 within which a set of instructions, for causing the machine to perform any one or more of the methodologies discussed herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein. In one embodiment, computer system 1200 is suitable for use as computing device 1112 described in association with FIG. 11 and/or control boxes 814 or 914 described in association with FIGS. 8 and 9, respectively. In an embodiment, computer system 1200 is configured to control one or more electromagnets housed in a cathode liner of an electrostatic chuck.

The exemplary computer system 1200 includes a processor 1202, a main memory 1204 (e.g., read-only memory (ROM), flash memory, dynamic random access memory (DRAM) such as synchronous DRAM (SDRAM) or Rambus DRAM (RDRAM), etc.), a static memory 1206 (e.g., flash memory, static random access memory (SRAM), etc.), and a secondary memory 1218 (e.g., a data storage device), which communicate with each other via a bus 1230.

Processor 1202 represents one or more general-purpose processing devices such as a microprocessor, central processing unit, or the like. More particularly, the processor 1202 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 1202 may also be one or more special-purpose processing devices such as an application specific integrated circuit (ASIC), a field programmable gate array (FPGA), a digital signal processor (DSP), network processor, or the like. Processor 1202 is configured to execute the processing logic 1226 for performing the operations discussed herein.

The computer system 1200 may further include a network interface device 1208. The computer system 1200 also may include a video display unit 1210 (e.g., a liquid crystal display (LCD) or a cathode ray tube (CRT)), an alphanumeric input device 1212 (e.g., a keyboard), a cursor control device 1214 (e.g., a mouse), and a signal generation device 1216 (e.g., a speaker).

The secondary memory 1218 may include a machine-accessible storage medium (or more specifically a computer-readable storage medium) 1231 on which is stored one or more sets of instructions (e.g., software 1222) embodying any one or more of the methodologies or functions described herein. The software 1222 may also reside, completely or at least partially, within the main memory 1204 and/or within the processor 1202 during execution thereof by the computer system 1200, the main memory 1204 and the processor 1202 also constituting machine-readable storage media. The software 1222 may further be transmitted or received over a network 1220 via the network interface device 1208.

While the machine-accessible storage medium 1231 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present invention. The term “machine-readable storage medium” shall accordingly be taken to include, but not be limited to, solid-state memories, and optical and magnetic media.

Thus, electrostatic chucks with magnetic cathode liners for critical dimension (CD) tuning have been disclosed.

What is claimed is:

1. An electrostatic chuck (ESC), comprising:
a cathode region;
a wafer processing region disposed above the cathode region; and
a magnetic cathode liner surrounding the cathode region, below the wafer processing region, the magnetic cathode liner configured to provide magnetic field tuning capability for the ESC.

2. The ESC of claim 1, wherein the magnetic cathode liner comprises one or more electromagnets.

3. The ESC of claim 1, wherein the magnetic cathode liner comprises a first ring-shaped electromagnet having a first diameter, and a second ring-shaped electromagnet having a second, larger, diameter.

4. The ESC of claim 3, wherein the first and second ring-shaped electromagnets share a common center point.

5. The ESC of claim 3, wherein the first and second ring-shaped electromagnets have upper surfaces that share a common plane with respect to a cross-sectional orientation of the ESC.

6. The ESC of claim 5, wherein the common plane is below the wafer processing region.

7. A semiconductor processing system, comprising:
a chamber coupled to an evacuation device, a gas inlet device, a plasma ignition device, and a detector;
a computing device coupled with the plasma ignition device;
a voltage source coupled with a sample holder comprising an electrostatic chuck (ESC), the ESC disposed in the chamber and comprising:
a cathode region;
a wafer processing region disposed above the cathode region; and
a magnetic cathode liner surrounding the cathode region, below the wafer processing region, the magnetic cathode liner configured to provide magnetic field tuning capability for the ESC, the magnetic cathode liner comprising one or more electromagnets; and
an electrical source coupled to the one or more electromagnets of the magnetic cathode liner.

8. The semiconductor processing system of claim 7, wherein the one or more electromagnets of the magnetic cathode liner comprises a first ring-shaped electromagnet having a first diameter, and a second ring-shaped electromagnet having a second, larger, diameter.

9. The semiconductor processing system of claim 8, wherein the first and second ring-shaped electromagnets share a common center point.

10. The semiconductor processing system of claim 8, wherein the first and second ring-shaped electromagnets have upper surfaces that share a common plane with respect to a cross-sectional orientation of the ESC.

11. The semiconductor processing system of claim 10, wherein the common plane is below the wafer processing region.

12. An electrostatic chuck (ESC), comprising:
a ceramic plate having a front surface and a back surface, the front surface for supporting a wafer or substrate;
a base coupled to the back surface of the ceramic plate;
a plurality of pixelated elements disposed in the base; and
a magnetic cathode liner surrounding the ceramic plate and base, the magnetic cathode liner and the plurality of pixelated elements configured to provide plasma tuning capability in regions local to the ESC.

13. The ESC of claim 12, wherein the plurality of pixelated elements is a plurality of electromagnets.

14. The ESC of claim 12, wherein the plurality of pixelated elements is a plurality of optical fibers.

15. The ESC of claim 14, wherein the plurality of optical fibers is configured to provide pixelated light-based heating capability for the ESC.

16. The ESC of claim 12, wherein the magnetic cathode liner comprises one or more electromagnets.

17. The ESC of claim 12, wherein the magnetic cathode liner comprises a first ring-shaped electromagnet having a first diameter, and a second ring-shaped electromagnet having a second, larger, diameter.

18. The ESC of claim 17, wherein the first and second ring-shaped electromagnets share a common center point.

19. The ESC of claim 17, wherein the first and second ring-shaped electromagnets have upper surfaces that share a common plane with respect to a cross-sectional orientation of the ceramic plate.

20. The ESC of claim 19, wherein the common plane is below the front surface of the ceramic plate with respect to the cross-sectional orientation of the ceramic plate.
